(19) United States
(12) Patent Application Publication
(10) Pub. No.: US 2026/0255635 A1
(43) Pub. Date: Aug. 27, 2026

(54) THIN FILM TRANSISTOR, ARRAY SUBSTRATE, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jun WANG, Beijing (CN); Yongliang ZHAO, Beijing (CN); Lang LIU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/995,416

(22) PCT Filed: Mar. 29, 2024
(86) PCT No.: PCT/CN2024/084777

§ 371 Date: Jan. 16, 2025

(30) Foreign Application Priority Data
Apr. 24, 2023 (CN) 202310451390.3

(51) Int. Cl. H10D 30/67; H10D 86/60

(52) U.S. Cl. CPC H10D 30/6757; H10D 86/60

(57) ABSTRACT

A thin film transistor, an array substrate, and a display device are provided. The thin film transistor includes an active layer, a first gate insulating layer, and a first gate electrode, the active layer includes a channel region and a first conductive region and a second conductive region separated by the channel region; the first gate insulating layer is on a first side of the active layer; the first gate electrode is on a side of the first gate insulating layer away from the active layer, at least part of the first conductive region, at least part of the channel region and at least part of the second conductive region are arranged in a first direction, the channel region includes a narrowed portion, and an average size of the narrowed portion in the first direction is smaller than an average size of the channel region in the first direction.

The present application claims the priority of the Chinese Patent Application No. 202310451390.3 filed on Apr. 24, 2023, the entire contents disclosed by the Chinese patent application are hereby incorporated by reference as a part of the present application.

### TECHNICAL FIELD

Embodiments of the present disclosure relates to a thin film transistor, an array substrate, and a display device.

### BACKGROUND

With the continuous development of display technology, the liquid crystal display (LCD) device and the organic light emitting diode (OLED) display device have gradually become the mainstream display devices. Both the liquid crystal display device and the organic light emitting diode display device need to use pixel driving circuits to drive the sub-pixels to display; the thin film transistor is a very important element in the pixel driving circuit, which directly affects the driving performance of the pixel driving circuit.

On the other hand, compared with silicon-based thin film transistors, the carrier concentration of oxide thin film transistors is about ten times that of silicon-based thin film transistors, and the carrier mobility of oxide thin film transistors is 20-30 times that of silicon-based thin film transistors. Therefore, the oxide thin film transistor can greatly improve the charging and discharging rate of the thin film transistor, improve the response speed of the sub-pixel, and further realize a faster refresh rate, so that the oxide thin film transistor can meet the application scenarios that require rapid response and large current, such as high-frequency, high-resolution and large-size liquid crystal display devices and organic light emitting diode display devices.

### SUMMARY

The embodiments of the present disclosure provide a thin film transistor, an array substrate and a display device. By designing a special-shaped channel region including a narrowed portion, the channel lengths of different regions of the channel region are different, so that the thin film transistor produces a leading/pilot effect similar to the Hump Effect, thereby increasing the subthreshold swing of the thin film transistor, and further improving the data voltage range (Data Range) of the driving transistor, so that the driving current provided by the driving transistor is insensitive to the fluctuation of the gate voltage.

At least one embodiment of the present disclosure provides a thin film transistor, which includes: an active layer, comprising a channel region and a first conductive region and a second conductive region separated by the channel region; a first gate insulating layer, on a first side of the active layer; and a first gate electrode, on a side of the first gate insulating layer away from the active layer, in which at least part of the first conductive region, at least part of the channel region and at least part of the second conductive region are arranged in a first direction, and the channel region comprises a narrowed portion, and an average size of the narrowed portion in the first direction is smaller than an average size of the channel region in the first direction.

For example, in the thin film transistor provided by an embodiment of the present disclosure, the first conductive region and the second conductive region are arranged opposite to each other and spaced part, and define a connection region between the first conductive region and the second conductive region, and the narrowed portion is in the connection region.

For example, in the thin film transistor provided by an embodiment of the present disclosure, the connection region comprises a center line extending in the first direction, and the narrowed portion is overlapped with the center line.

For example, in the thin film transistor provided by an embodiment of the present disclosure, the first conductive region is on a first side of the channel region and the second conductive region is on a second side of the channel region; the narrowed portion is narrowed from the first side and the second side to a center line of the channel region extending in a second direction intersecting with the first direction.

For example, in the thin film transistor provided by an embodiment of the present disclosure, the channel region comprises a plurality of narrowed portions arranged in a second direction intersecting with the first direction.

For example, in the thin film transistor provided by an embodiment of the present disclosure, the plurality of narrowed portions are staggered in the first direction.

For example, in the thin film transistor provided by an embodiment of the present disclosure, at least one of the first conductive region and the second conductive region comprises a protrusion portion connected with the narrowed portion, and a shape of the protrusion portion is complementary to a shape of the narrowed portion.

For example, in the thin film transistor provided by an embodiment of the present disclosure, the channel region comprises a first edge and a second edge, the first edge is in contact with the first conductive region and the second edge is in contact with the second conductive region; at least one of the first edge and the second edge comprises a bent portion, and the bent portion is bent from the first conductive region or the second conductive region to the channel region.

For example, in the thin film transistor provided by an embodiment of the present disclosure, the bent portion comprises at least one of an oblique line and an arc line, and an included angle between the oblique line and the first direction is less than 90 degrees.

For example, in the thin film transistor provided by an embodiment of the present disclosure, the first edge comprises a first bent portion bending from the first conductive region to the channel region, and the second edge comprises a second bent portion bending from the second conductive region to the channel region.

For example, in the thin film transistor provided by an embodiment of the present disclosure, the first bent portion and the second bent portion are overlapped in the first direction.

For example, in the thin film transistor provided by an embodiment of the present disclosure, a size of the first bent portion in the first direction is greater than a size of the second bent portion in the first direction, or, a size of the first bent portion in the first direction is smaller than a size of the second bent portion in the first direction.

For example, in the thin film transistor provided by an embodiment of the present disclosure, a ratio of an area of the narrowed portion to an area of the channel region ranges from 1/16 to 3/16.

For example, in the thin film transistor provided by an embodiment of the present disclosure, a smallest size of the narrowed portion in the first direction is greater than or equal to 1 micron, and a ratio of a size of the narrowed portion in a second direction intersecting with the first direction to a size of the channel region in the second direction ranges from 10% to 20%.

For example, the thin film transistor provided by an embodiment of the present disclosure further comprises: a second gate insulating layer, on a second side of the active layer; and a second gate electrode, on a side of the second gate insulating layer away from the active layer, in which an orthographic projection of the second gate electrode on the active layer completely covers an orthographic projection of the first gate electrode on the active layer.

For example, in the thin film transistor provided by an embodiment of the present disclosure, the channel region comprises a first edge and a second edge, the first edge is in contact with the first conductive region and the second side is in contact with the second conductive region; a shortest distance between the first edge and an edge of an orthographic projection of the second gate electrode on the active layer is greater than 1.0 micron; a shortest distance between the second edge and an edge of the orthographic projection of the second gate electrode on the active layer is greater than 1.0 micron.

For example, the thin film transistor provided by an embodiment of the present disclosure further comprises: a first electrode, electrically connected with the first conductive region; and a second electrode, electrically connected with the second conductive region, in which the first electrode is electrically connected with the second gate electrode.

For example, in the thin film transistor provided by an embodiment of the present disclosure, the first conductive region is a source region and the second conductive region is a drain region; or, the first conductive region is a drain region and the second conductive region is a source region.

At least one embodiment of the present disclosure provides an array substrate, which comprises: a base substrate; and the thin film transistor according to any one of the above embodiments.

For example, the array substrate provided by an embodiment of the present disclosure further comprises: a plurality of pixel driving circuits arranged in an array, in which each of the plurality of pixel driving circuits comprises a driving thin film transistor, and the driving thin film transistor comprises the thin film transistor.

For example, in the array substrate provided by an embodiment of the present disclosure, the plurality of pixel driving circuits comprise: a first pixel driving circuit, configured to drive a first sub-pixel to emit light of a first color; a second pixel driving circuit, configured to drive a second sub-pixel to emit light of a second color; and a third pixel driving circuit, configured to drive a third sub-pixel to emit light of a third color, in which a size of the narrowed portion of the driving thin film transistor of the first pixel driving circuit, a size of the narrowed portion of the driving thin film transistor of the second pixel driving circuit and a size of the narrowed portion of the driving thin film transistor of the third pixel driving circuit are different.

At least one embodiment of the present disclosure provides a display device, which comprises the array substrate according to any one of the above embodiments.

At least one embodiment of the present disclosure provides a thin film transistor, which comprises: an active layer, comprising a channel region, and a first conductive region and a second conductive region separated by the channel region; a first gate insulating layer, on a first side of the active layer; and a first gate electrode, on a side of the first gate insulating layer away from the active layer, in which at least part of the first conductive region, at least part of the channel region and at least part of the second conductive region are arranged in a first direction; the channel region comprises a first edge and a second edge, the first edge is in contact with the first conductive region and the second edge is in contact with the second conductive region, and at least one of the first edge and the second edge comprises a bent portion, and the bent portion is bent from the first conductive region or the second conductive region to the channel region.

For example, in the thin film transistor provided by an embodiment of the present disclosure, the first edge comprises a first bent portion bending from the first conductive region to the channel region, and the second edge comprises a second bent portion bending from the second conductive region to the channel region.

For example, the thin film transistor provided by an embodiment of the present disclosure further comprises: a second gate insulating layer, on a second side of the active layer; and a second gate electrode, on a side of the second gate insulating layer away from the active layer, in which an orthographic projection of the second gate electrode on the active layer completely covers an orthographic projection of the first gate electrode on the active layer.

### BRIEF DESCRIPTION OF DRAWINGS

In order to illustrate the technical solutions of the embodiments of the present disclosure more clearly, the attached drawings of the embodiments will be briefly introduced below. Obviously, the attached drawings in the following description only relate to some embodiments of the present disclosure, and are not used to limit to the present disclosure.

FIG. 1 is a schematic diagram of a pixel driving circuit;

FIG. 2 is a schematic plan view of a thin film transistor provided by an embodiment of the present disclosure;

FIG. 3 is a schematic sectional view of a thin film transistor provided by an embodiment of the present disclosure;

FIG. 4A is a graph of curves of output currents of a main portion and a part of a narrowed portion of a thin film transistor provided by an embodiment of the present disclosure;

FIG. 4B is a graph of a curve of the final output current of a main portion and a part of a narrowed portion of a thin film transistor provided by an embodiment of the present disclosure;

FIG. 5 is a graph of a curve of the output current of a thin film transistor provided by an embodiment of the present disclosure;

FIG. 6 is a schematic plan view of another thin film transistor provided by an embodiment of the present disclosure;

FIG. 7 is a schematic sectional view of another thin film transistor provided by an embodiment of the present disclosure;

FIG. 8 is a schematic plan view of another thin film transistor provided by an embodiment of the present disclosure;

FIG. 9 is a schematic sectional view of another thin film transistor provided by an embodiment of the present disclosure;

FIG. 10 is a schematic plan view of another thin film transistor provided by an embodiment of the present disclosure;

FIG. 11 is a schematic sectional view of another thin film transistor provided by an embodiment of the present disclosure;

FIG. 12 is a schematic plan view of another thin film transistor provided by an embodiment of the present disclosure;

FIG. 13 is a schematic sectional view of another thin film transistor provided by an embodiment of the present disclosure;

FIG. 14 is a schematic plan view of another thin film transistor provided by an embodiment of the present disclosure;

FIG. 15 is a schematic sectional view of another thin film transistor provided by an embodiment of the present disclosure;

FIG. 16 is a schematic plan view of another thin film transistor provided by an embodiment of the present disclosure;

FIG. 17 is a schematic sectional view of another thin film transistor provided by an embodiment of the present disclosure;

FIG. 18 is a schematic plan view of another thin film transistor provided by an embodiment of the present disclosure;

FIG. 19 is a schematic plan view of another thin film transistor provided by an embodiment of the present disclosure;

FIG. 20 is a schematic plan view of another thin film transistor provided by an embodiment of the present disclosure;

FIG. 21 is a schematic plan view of an array substrate provided by an embodiment of the present disclosure;

FIG. 22A is a schematic plan view of a driving thin film transistor provided by an embodiment of the present disclosure;

FIG. 22B is a schematic plan view of another driving thin film transistor provided by an embodiment of the present disclosure; and

FIG. 23 is a schematic plan view of a display device provided by an embodiment of the present disclosure.

### DETAILED DESCRIPTION

In order to make the purpose, technical solutions and advantages of the technical solutions of the present disclosure more clear, the technical solutions of the embodiments of the present disclosure will be described clearly and completely with the accompanying drawings of the embodiments of the present disclosure. It should be noted that the described embodiment is a part of the embodiments of the present disclosure, not the whole embodiments. Based on the described embodiments of the present disclosure, all other embodiments obtained by ordinary people in the field without creative labor belong to the scope of protection of the present disclosure.

Unless otherwise defined, technical terms or scientific terms used in the present disclosure shall have their ordinary meanings as understood by people with ordinary skills in the field to which the present disclosure belongs. The terms “first”, “second” and the like used in the present disclosure do not indicate any order, quantity or importance, but are only used to distinguish different components. Similar words such as “including/comprising” or “containing” are intended to specify that the elements or the objects stated before these terms encompass the elements or the objects and equivalents thereof listed after these terms, but do not preclude the other elements or objects. Similar words such as “connecting” or “connected” are not limited to physical or mechanical connection, but can include electrical connection, whether direct or indirect.

Unless otherwise defined, the features such as “parallel”, “vertical/perpendicular” and “identical/same” used in the embodiments of the present disclosure all include cases such as “parallel”, “vertical/perpendicular” and “identical/same” in a strict sense, and cases such as “substantially parallel”, “substantially vertical/perpendicular” and “substantially identical/same” contain certain errors. For example, the above-mentioned “substantially” can mean the difference of the compared objects is within 10% or 5% of the average value of the compared objects. When the number of one component or element is not specified in the following of the embodiments of the present disclosure, it means that the component or element can be one or more, or can be understood as at least one. “At least one” means one or more, and “a plurality of” means at least two.

In an organic light emitting diode display device, each sub-pixel includes a pixel driving circuit and a light emitting element; the light emitting element includes an anode, a cathode and an organic light emitting layer located between the anode and the cathode, and the pixel driving circuit is connected with the anode to provide a current signal to the anode, thereby driving the light emitting element to emit light. Usually, the pixel driving circuit includes thin film transistors and at least one capacitor; for example, the pixel driving circuit can adopt a 3T1C structure, a 5T1C structure, a 7T1C structure or an 8T1C structure, in which T represents the thin film transistor and C represents the capacitor.

Hereinafter, the pixel driving circuit will be briefly described by taking the 7T1C structure as an example, FIG. 1 is a schematic diagram of a pixel driving circuit. As illustrated by FIG. 1, the pixel driving circuit includes a driving transistor T1, a compensation transistor T3, a data writing transistor T2, a first light emission control transistor T4, a second light emission control transistor T5, an initialization transistor T6 and an electrode reset transistor T7; a first electrode of the driving transistor T1, a second electrode of the data writing transistor T2 and a second electrode of the first light emission control transistor T4 are electrically connected; a second electrode of the driving transistor T1, a first electrode of the compensation transistor T3 and a first electrode of the second light emission control transistor T5 are electrically connected; a gate electrode of the driving transistor T1, a second electrode of the compensation transistor T3 and a second electrode of the initialization transistor T6 are electrically connected; a second electrode of the second light emission control transistor T5, a second electrode of the electrode reset transistor T7 and an anode of the light emitting element 10 are electrically connected. A first electrode plate of the storage capacitor Cst is connected with a first electrode of the first light emission control transistor T4 and configured to be connected with a power supply voltage, and a second electrode plate of the storage capacitor Cst is electrically connected with the gate electrode of the driving transistor T1, the second electrode of the compensation transistor T3 and the second electrode of the initialization transistor T6.

As illustrated by FIG. 1, the electrode reset transistor T7 is configured to reset the anode of the light emitting element 10 in response to a reset signal, and the initialization transistor T6 is configured to initialize the gate electrode of the driving transistor T1 and the second electrode plate of the storage capacitor Cst in response to the reset signal. Subsequently, the data writing transistor T2 and the compensation transistor T3 can be turned on through a gate signal Gate, and a data signal Vd can be transmitted through the data writing transistor T2; in this case, the driving transistor T1 is turned on, and the data signal Vd is applied to the gate electrode of the driving transistor T1 through the data writing transistor T2 and the compensation thin film transistor T3. In this case, the voltage applied to the gate electrode of the driving transistor T1 is a compensation voltage Vd+Vth, and the compensation voltage applied to the gate electrode of the driving transistor T1 is also applied to the second electrode plate of the storage capacitor Cst. Subsequently, a driving voltage Vel is applied to the first electrode plate of the storage capacitor Cst, and the voltage on the second electrode plate is the compensation voltage Vd+Vth, so that charges corresponding to the voltage difference between the voltages respectively applied to the two electrode plates of the storage capacitor Cst are stored in the storage capacitor Cst, and the driving transistor T1 is driven to be turned on for predetermined time. Subsequently, both the first light emission control transistor T4 and the second light emission control transistor T5 are turned on, and when the driving signal Vel passes through the driving transistor T1 which is turned on by the storage capacitor Cst, the voltage of the first electrode of the driving transistor T1 is Vel, and the voltage of the gate electrode of the driving transistor T1 is Vd+Vth, so that the driving transistor T1 can be in a saturated state, so that the driving transistor T1 generates a driving current Ids; then, the driving current Ids is applied to the anode of the light emitting element 10 through the second light emission control transistor T5, so that the light emitting element emits light.

As mentioned above, the driving transistor T1 provides the driving current for the anode of the light emitting element 10 during the light emitting process of the light emitting element 10, so as to keep the current of the driving transistor T1 stable during the light emitting period (one frame) of the light emitting element 10, which can significantly improve the display quality and eliminate or alleviate the Mura defect. By increasing the subthreshold swing (SS) of the driving transistor, the data voltage range (Data Range) of the driving transistor can be improved, so that the driving current provided by the driving transistor is insensitive to the fluctuation of the gate voltage, thereby reducing the sensitivity of the luminous brightness of the light emitting element to the voltage fluctuation, and obviously improving the display quality and eliminating or alleviating the Mura defect.

On the other hand, in the high generation line, oxide thin film transistor (Oxide TFT) has great advantages in cost, uniformity and leakage, and has become a research hotspot and development direction of major manufacturers. However, the inventor(s) of the present application found that in the common low-temperature polysilicon thin film transistor (LTPS TFT), the driving transistor can obtain a larger subthreshold swing by changing the channel length, while the current subthreshold swing of the oxide thin film transistor is insensitive to the channel length, and it is impossible to obtain a larger subthreshold swing by designing different channel lengths, so how to obtain a larger subthreshold swing for the driving transistor by other means is an urgent problem to be solved. It should be noted that the channel length of the channel region of a common thin film transistor is uniform in different regions, so the abovementioned way to change the channel length is to increase or decrease the channel length as a whole.

In view of the above problems, the embodiments of the present disclosure provide a thin film transistor. The thin film transistor includes an active layer, a first gate insulating layer and a first gate electrode; the active layer includes a channel region and a first conductive region and a second conductive region separated by the channel region; the first gate insulating layer is located on a first side of the active layer; the first gate electrode is located on a side of the first gate insulating layer away from the active layer; at least part of the first conductive region, at least part of the channel region and at least part of the second conductive region are arranged in a first direction, and the channel region includes a narrowed portion, and an average size of the narrowed portion in the first direction is smaller than an average size of the channel region in the first direction. Therefore, by designing a special-shaped channel region including the narrowed portion, the channel lengths of different regions of the channel region are different, so that the thin film transistor generates a leading/pilot effect similar to the Hump Effect, thereby increasing the subthreshold swing of the thin film transistor, and further improving the data voltage range (Data Range) of the driving transistor, so that the driving current provided by the driving transistor is insensitive to the fluctuation of the gate voltage.

The embodiments of the present disclosure further provide an array substrate, which includes the above thin film transistor. Therefore, the array substrate can use the thin film transistor with a large subthreshold swing as the driving transistor, so that the driving current provided by the driving transistor is insensitive to voltage fluctuation, thereby reducing the sensitivity of the luminous brightness of the sub-pixel to voltage fluctuation, thus significantly improving the display quality and eliminating or alleviating the Mura defect.

The embodiments of the disclosure further provide a display device, which includes the above array substrate. Therefore, the display device can have better display quality, eliminate or alleviate the Mura defect, and can also be applied to electronic products requiring high frequency, high resolution and large size.

Hereinafter, the thin film transistor, the array substrate and the display device provided by the embodiments of the present disclosure will be described in detail with reference to the accompanying drawings.

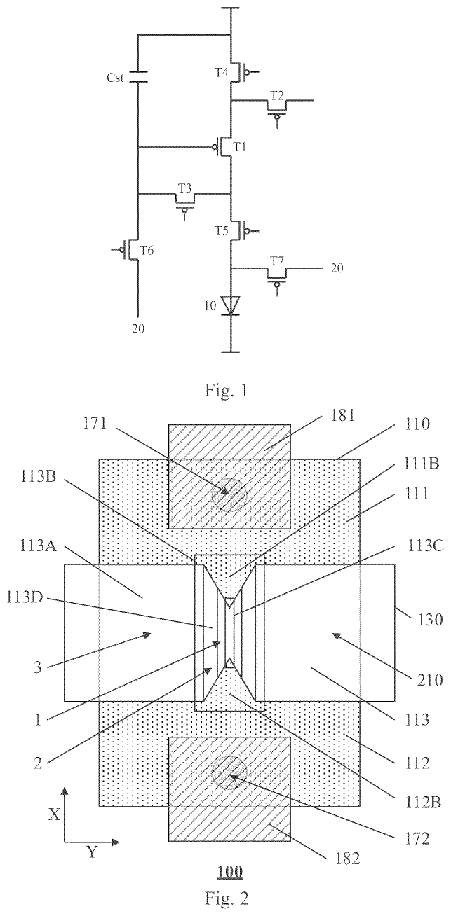

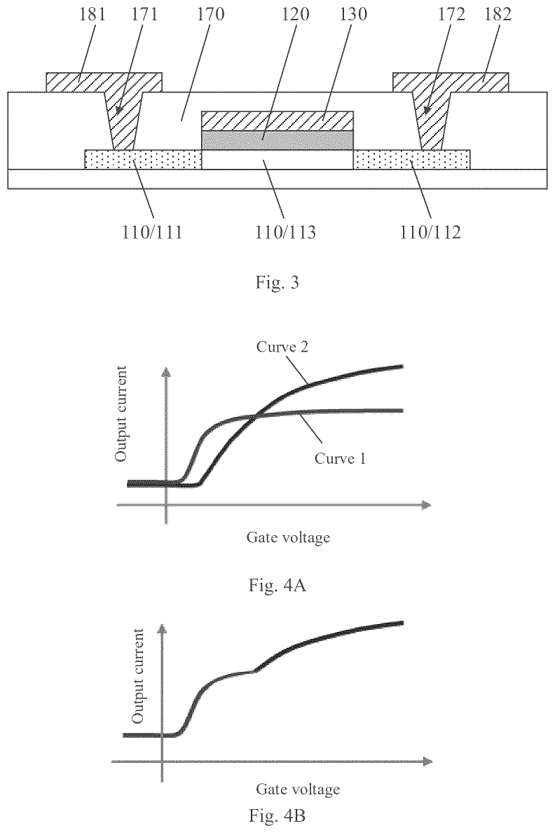

An embodiment of the present disclosure provides a thin film transistor. FIG. 2 is a schematic plan view of a thin film transistor provided by an embodiment of the present disclosure; and FIG. 3 is a schematic sectional view of a thin film transistor provided by an embodiment of the present disclosure.

As illustrated by FIG. 2 and FIG. 3, the thin film transistor 100 includes an active layer 110, a first gate insulating layer 120 and a first gate electrode 130; the active layer 110 includes a channel region 113 and a first conductive region 111 and a second conductive region 112 separated by the channel region 113, and the conductivity of the first conductive region 111 and the conductivity of the second conductive region 112 are greater than the conductivity of the channel region 113. The first gate insulating layer 120 is located on a first side of the active layer 110, the first side is a side in a direction perpendicular to a main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as a length direction of the channel region 113. The channel region 113 includes a narrowed portion 113B, and an average size of the narrowed portion 113B in the first direction X is smaller than an average size of the channel region 113 in the first direction X, that is, an average channel length of the narrowed portion 113B is smaller than an average channel length of the whole channel region 113.

In the thin film transistor provided by the embodiments of the present disclosure, because the channel region includes the narrowed portion, and the average size of the narrowed portion in the first direction is smaller than the average size of the channel in the first direction, the channel region has a smaller channel length in the narrowed portion and a larger channel length in other portions (which can also be called the main portion). In this case, taking the channel region of the thin film transistor is an N-type channel region as an example, when the gate voltage on the first gate electrode is not enough to turn on the other portions of the channel region and only the narrowed portion can be turned on, the thin film transistor can generate a leading/pilot effect similar to the Hump Effect, the narrowed portion is turned on, and the output current of the thin film transistor is mainly on the narrowed portion; when the gate voltage on the first gate electrode is increased to turn on other portions of the channel region, other portions can also be turned on, and the output current of the thin film transistor is mainly on other portions. Therefore, by designing a special-shaped channel region including the narrowed portion, the channel lengths of different regions of the channel region are different, so that the thin film transistor produces a leading/pilot effect similar to the Hump Effect, and the subthreshold swing of the thin film transistor is increased, thereby improving the data voltage range of the thin film transistor, and further making the driving current provided by the driving transistor insensitive to voltage fluctuations. When a display device adopts the thin film transistor as the driving transistor, the display quality can be significantly improved and the Mura defect can be eliminated or alleviated. It is worth noting that the above pilot effect reflects the relationship between the gate voltage and the output current. When the thin film transistor is applied to the pixel driving circuit of a display device, the thin film transistor can work in the saturation region (the saturation region reflects the relationship between the drain-source voltage and the output current).

It should be noted that under a specific drain-source voltage Vds, different data voltages (corresponding to the gate voltage) correspond to different output currents, thus corresponding to different brightness or gray scales of light emitting elements or sub-pixels; the above data voltage range (Data Range) is the difference between the gate voltages Vg or the gate-source voltages Vgs corresponding to the output currents corresponding to two gray scales; when the value of the data voltage range is larger, the change of output current caused by gate voltage fluctuation or error is smaller, and the corresponding brightness or gray scale error is smaller. Therefore, improving the data voltage range (Data Range) of the thin film transistor can make the driving current insensitive to voltage fluctuation, improve the accuracy of the gray scale displayed by the sub-pixel, thus significantly improving the display quality and eliminating or alleviating the Mura defect.

On the other hand, increasing the subthreshold swing of the thin film transistor can increase the range of the gate voltage driving the thin film transistor to generate the driving current (for example, 10⁻¹¹ A to 10⁻⁷ A) for driving the light emitting element, and the driving currents correspond to different gray scales of the light emitting element or sub-pixel. Therefore, when the abovementioned subthreshold swing is increased, the range of the gate voltage is also increased, and the range of the gate voltage allocated to a single gray scale is also increased, that is, the data voltage range (Data Range) is increased.

In some examples, as illustrated by FIG. 2 and FIG. 3, the channel region 113 further includes a main portion 113A connected with the narrowed portion 113B, and a size of the main portion 113A in the first direction X is greater than the maximum size of the narrowed portion 113B in the first direction X. For example, channel lengths of the main portion 113A at different positions in the second direction Y intersecting with the first direction X are approximately equal. It should be noted that the main portion may be the other portions mentioned above; in addition, the main portion may be located on a side of the narrowed portion or on both sides of the narrowed portion.

In some examples, as illustrated by FIG. 2 and FIG. 3, the first conductive region 111 may be a source region, and the second conductive region 112 may be a drain region. Alternatively, the first conductive region 111 may be a drain region, and the second conductive region 112 may be a source region.

In some examples, the first conductive region 111 and the second conductive region 112 may be conductive by a doping method. Of course, the embodiments of the present disclosure include but are not limited thereto, and the abovementioned first conductive region and second conductive region can also be conductive by other methods.

FIG. 4A is a graph of curves of the output currents of a main portion and a part of a narrowed portion of a thin film transistor provided by an embodiment of the present disclosure; and FIG. 4B is a graph of a curve of the final output current of a main portion and a part of a narrowed portion of a thin film transistor provided by an embodiment of the present disclosure. The abovementioned part of the narrowed portion refers to a portion with a certain width in the narrowed portion.

As illustrated by FIG. 4A and FIG. 4B, the curve 1 shows the output current of a part of the narrowed portion with a certain channel length, and curve 2 shows the output current of the main portion. It can be seen that when the gate voltage on the first gate electrode is not enough to turn on the main portion, and only the narrowed portion can be turned on, the thin film transistor can generate a pilot effect similar to the Hump Effect, the narrowed portion is turned on, and the output current of the thin film transistor is mainly on the narrowed portion; when the gate voltage on the first gate electrode is increased to turn on other portions of the channel region, other portions can also be turned on, and the output current of the thin film transistor is mainly on other portions.

In some examples, as illustrated by FIG. 2 and FIG. 3, the narrowed portion 113B includes an extremely narrowed portion 113C, and a size of the extremely narrowed portion 113C in the first direction X is the smallest size of the narrowed portion 113B in the first direction X; the narrowed portion 113B is connected with the main portion 113A, and the size of the narrowed portion 113B in the first direction X gradually decreases from the connection position between the narrowed portion 113B and the main portion 113A to the extremely narrowed portion 113C.

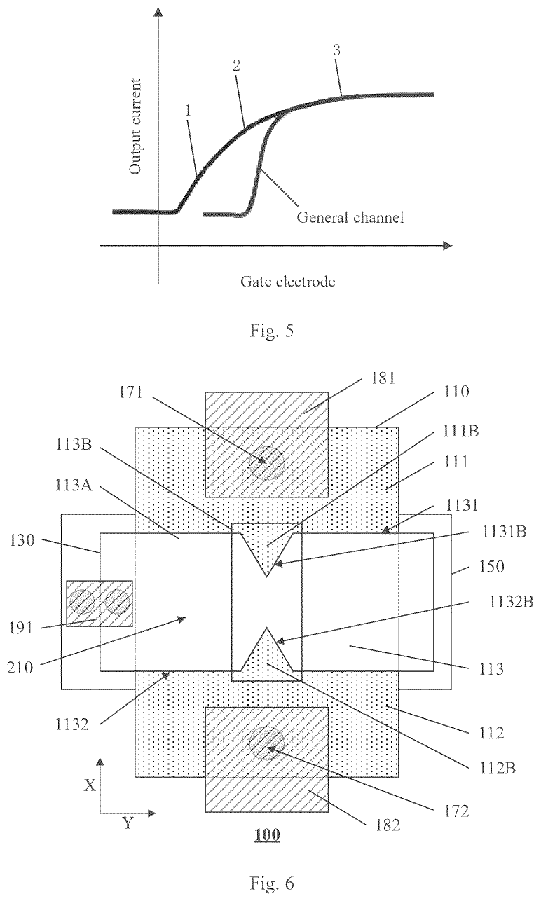

FIG. 5 is a graph showing a curve of the output current of a thin film transistor provided by an embodiment of the present disclosure. As illustrated by FIG. 5, because the size of the narrowed portion in the first direction X is gradually reduced from the connection position between the narrowed portion and the main portion to the extremely narrow portion, the narrowed portion can be regarded as a combination of a plurality of sub-portions with different channel lengths, and each of the plurality of sub-portions can generate the abovementioned hump effect, so that the sub-portions together make the final output current curve of the thin film transistor be a smooth curve, different gate voltages can better correspond to different output currents, and further, the thin film transistor can work more stably, and avoid generating gray scale fault and the like.

For example, as illustrated by FIG. 2 and FIG. 5, the narrowed portion 113B can be divided into a first sub-portion 1 and two second sub-portions 2 located on both sides of the first sub-portion 1, and the main portion 113A includes two third sub-portions 3 located on sides of the two second sub-portions 2 away from the first sub-portion 1. As illustrated by FIG. 5, with the increase of the gate voltage on the first gate electrode, the first sub-portion 1 is turned on first, then the second sub-portions 2 are turned on, and finally the third sub-portions 3 are turned on, thus forming a smooth output current curve by superposition.

In some examples, as illustrated by FIG. 2, the narrowed portion 113B includes an edge extending from the main portion 113A to the extremely narrowed portion 113C, and the shape of the edge includes an oblique line, so that the size of the narrowed portion can be gradually reduced in the first direction X. Of course, the embodiments of the present disclosure include but are not limited thereto, and the abovementioned edge may also include an arc line, a step-shaped line, and the like. It should be noted that the above oblique line refers to a straight line with an included angle of less than 90 degrees with the first direction X.

In some examples, a ratio of the width of the narrowed portion 113B in the second direction Y intersecting with the first direction X to a width of the channel region 113 in the second direction Y is less than 20%. This arrangement can ensure that the final output current of the thin film transistor is still dominated by the main portion.

In some examples, a ratio of the area of the narrowed portion 113B to the area of the channel region 113 ranges from 1/16 to 3/16. Therefore, the thin film transistor can avoid the thin film transistor only showing the characteristics of the narrowed portion while having a better pilot effect.

In some examples, the smallest size of the narrowed portion 113B in the first direction X is greater than or equal to 1 micron, and a ratio of the size of the narrowed portion 113B in the second direction Y intersecting with the first direction X to the size of the channel region 113 in the second direction Y ranges from 10% to 20%. Therefore, the thin film transistor can avoid the thin film transistor only showing the characteristics of the narrowed portion while having a better pilot effect.

In some examples, as illustrated by FIG. 2, the first conductive region 111 and the second conductive region 112 are arranged opposite to each other and spaced part and define a connection region 210 between the first conductive region 111 and the second conductive region 112, and the narrowed portion 113B is located in the connection region 210. The connection region 210 is overlapped with both the first conductive region 111 and the second conductive region 112 in the first direction X. Therefore, the narrowed portion can better produce the abovementioned piolet effect.

In some examples, as illustrated by FIG. 2, the connection region 210 includes a center line extending in the first direction X, and the narrowed portion 113B is overlapped with the center line. Therefore, when manufacturing the abovementioned thin film transistors on a large scale, for example, when applied to an array substrate, the arrangement that the narrowed portion is overlapped with the central line of the connection region extending along the first direction X can avoid the performance differences of different thin film transistors caused by process errors. It should be noted that when the narrowed portion is formed at an edge region of the channel region, if some thin film transistors have process errors, the area of the narrowed portion may be smaller, but if the narrowed portion is overlapped with the central line extending along the first direction X, even if some thin film transistors have process errors, the narrowed portion is still located in the connection region, and its area remains unchanged.

In some examples, as illustrated by FIG. 2, the narrowed portion 113B includes a transition portion 113D connected with the extremely narrowed portion 113C and the main portion 113A; the extremely narrowed portion 113C may be a linear portion extending along the first direction X or a strip portion extending along the first direction X, that is, the planar shape of the extremely narrowed portion 113C includes a linear shape or a strip shape; in this case, the shape of the transition portion 113D includes a trapezoid.

In some examples, as illustrated by FIG. 2, the first conductive region 111 is located on a first side of the channel region 113, and the second conductive region 112 is located on a second side of the channel region 113; the narrowed portion 113B narrows from both the first side and the second side to the center line of the channel region 113 extending in the second direction Y intersecting with the first direction X, that is, narrows from both sides of the channel region. Therefore, the thin film transistor can make the first conductive region and the second conductive region have better symmetry. It should be noted that the first side and the second side of the channel region may be opposite sides in the first direction X.

In some examples, as illustrated by FIG. 2, at least one of the first conductive region 111 and the second conductive region 112 includes a protrusion portion 111B/112B connected with the narrowed portion 113B, and the shape of the protrusion portion 111B/112B is complementary to the shape of the narrowed portion 113B. That is, the regions on both sides of the narrowed portion in the first direction X are both conductive regions. Therefore, the narrowed portion can better produce the abovementioned piolet effect. In addition, in the manufacturing process of the thin film transistor, the shape of the protrusion portion and the shape of the narrowed portion are complementary, so that the active layer can be easily conducted by using the first gate electrode as a mask. It should be noted that the abovementioned “shapes are complementary” refers to that the plane shapes of the protrusion portion and the narrowed portion can be combined to form a rectangle.

In some examples, as illustrated by FIG. 2, the shape of the protrusion portion 111B/112B includes a triangle, so that the size of the narrowed portion in the first direction X can be gradually reduced, and the curve of the final output current of the thin film transistor can be a smooth curve, so that different gate voltages can better correspond to different output currents, and further, the thin film transistor can work more stably, and defects such as gray scale faults can be avoided. Of course, the embodiments of the present disclosure include but are not limited thereto, and the shape of the protrusion portion may also include at least one of a group consisting of trapezoid, semicircle and arch.

In some examples, as illustrated by FIG. 2, the first conductive region 111 includes a first protrusion portion 111B connected with the narrowed portion 113B, and the second conductive region 112 includes a second protrusion portion 112B connected with the narrowed portion 113. Both the first protrusion portion 111B and the second protrusion portion 112B are conductive regions.

In some examples, as illustrated by FIG. 2, the first protrusion portion 111B and the second protrusion portion 112B are mirror-image symmetrical with respect to the center line of the channel region 113 extending in the second direction Y. Therefore, the thin film transistor can make the first conductive region and the second conductive region have better symmetry.

In some examples, as illustrated by FIG. 2, a shape of an orthographic projection of the first gate electrode 130 on the active layer 110 is the same as a shape of the channel region 113C. Therefore, the first gate electrode can be used as a mask to perform a conductive process (such as a doping process) on the active layer to form the abovementioned special-shaped channel region.

In some examples, as illustrated by FIG. 2, the first gate electrode 130 may include a gate main portion corresponding to the main portion 113A of the channel region 113 and a gate narrowed portion corresponding to the narrowed portion 113B of the channel region 113. Because the shape of the orthographic projection of the first gate electrode on the active layer is the same as the shape of the channel region, the positional relationship between the gate main portion and the gate narrowed portion, and the shapes and sizes of the gate main portion and the gate narrowed portion themselves can be referred to the relevant descriptions and definitions of the main portion and narrowed portion of the channel region, and the repeated portions are omitted in the embodiments of the present disclosure.

In some examples, as illustrated by FIG. 2, the thin film transistor 100 further includes a first electrode 181 and a second electrode 182; the first electrode 181 is electrically connected with the first conductive region 111, the second electrode 182 is electrically connected with the second conductive region 112. The first electrode 181 may be a source electrode and the second electrode may be a drain electrode. Alternatively, the first electrode 181 may be a drain electrode and the second electrode 182 may be a source electrode.

In some examples, as illustrated by FIG. 2 and FIG. 3, a passivation layer 170 is provided between a layer where the first electrode 181 and the second electrode 182 are located and the active layer 110. The first electrode 181 is electrically connected with the first conductive region 111 of the active layer 110 through a first via 171 penetrating through the passivation layer 170, and the second electrode 182 is connected with the second conductive region 112 of the active layer 110 through a second via 172 penetrating through the passivation layer 170.

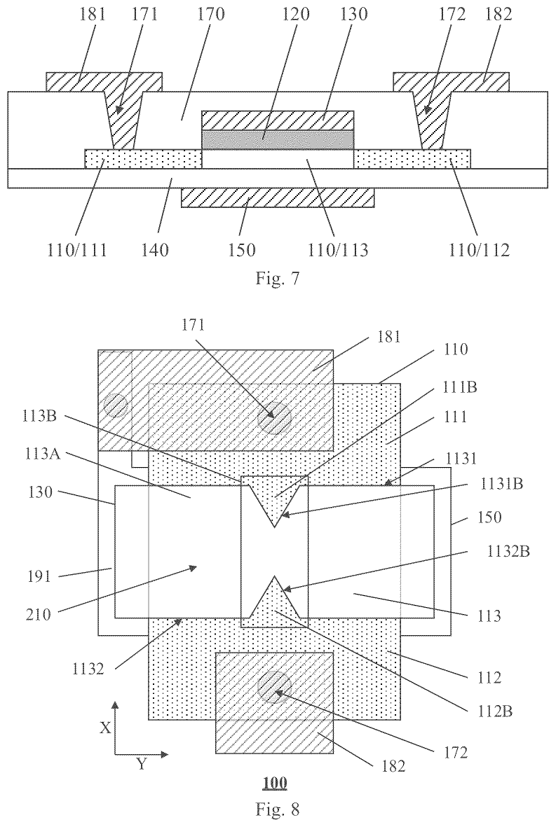

FIG. 6 is a schematic plan view of another thin film transistor provided by an embodiment of the present disclosure; FIG. 7 is a schematic cross-sectional view of another thin film transistor provided by an embodiment of the present disclosure.

As illustrated by FIG. 6 and FIG. 7, the thin film transistor 100 includes an active layer 110, a first gate insulating layer 120 and a first gate electrode 130; the active layer 110 includes a channel region 113 and a first conductive region 111 and a second conductive region 112 separated by the channel region 113, and the conductivity of the first conductive region 111 and the conductivity of the second conductive region 112 is greater than the conductivity of the channel region 113. The first gate insulating layer 120 is located on a first side of the active layer 110, the first side is a side in a direction perpendicular to the main surface of the active layer 110; the first gate electrode 130 is located on a side of the first gate insulating layer 120 away from the active layer 110.

As illustrated by FIG. 6, at least part of the first conductive region 111, at least part of the channel region 113 and at least part of the second conductive region 112 are arranged in the first direction X. For example, all of the first conductive region 111, all of the channel region 113 and all of the second conductive region 112 are arranged in the first direction X.

As illustrated by FIG. 6 and FIG. 7, the first direction X can also be regarded as a length direction of the channel region 113. The channel region 113 includes a narrowed portion 113B, and an average size of the narrowed portion 113B in the first direction X is smaller than an average size of the channel region 113 in the first direction X, that is, an average channel length of the narrowed portion 113B is smaller than an average channel length of the whole channel region 113. From another perspective, the channel region 113 includes a first edge 1131 and a second edge 1132, the first edge 1131 is in contact with the first conductive region 111 and the second edge 1132 is in contact with the second conductive region 112. At least one of the first edge 1131 and the second edge 1132 includes a bent portion 1131B/1132B, and the bent portion 1131B/1132B is bent from the first conductive region 111 or the second conductive region 112 to the channel region 113, thereby forming the abovementioned narrowed portion 113B.

In the thin film transistor provided by the embodiments of the present disclosure, because at least one of the first edge and the second edge of the channel region includes a bent portion, and the bent portion is bent from the first conductive region or the second conductive region to the channel region, a part of the channel region corresponding to the bent portion has a smaller channel length, and the other portions (also called the main portion) have larger channel lengths. In this case, taking the case that the channel region of the thin film transistor is an N-type channel as an example, when the gate voltage on the first gate electrode is not enough to turn on other portions of the channel region and only the part of the channel region corresponding to the bent portion can be turned on, the thin film transistor can generate a pilot effect similar to the Hump Effect, and the part of the channel region corresponding to the bent portion is turned on first, and the output current of the thin film transistor is mainly on this part; when the gate voltage on the first gate electrode is increased to turn on other portions of the channel region, other portions can also be turned on, and the output current of the thin film transistor is mainly on other portions. Therefore, by designing a special-shaped channel region including the bent portion, the thin film transistor has different channel lengths in different regions of the channel region, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated. For the principle of how increasing the subthreshold swing of the thin film transistor can increase the data voltage range (Data Range), please refer to the related descriptions for FIG. 2 and FIG. 3, which will not be repeated here.

In some examples, as illustrated by FIG. 6, the first direction X and the second direction Y are perpendicular to each other. Of course, the embodiments of the present disclosure include, but are not limited thereto, and the first direction and the second direction may also intersect and form an included angle not equal to 90 degrees.

In some examples, as illustrated by FIG. 6, the first edge 1131 includes a first bent portion 1131B bent from the first conductive region 111 to the channel region 113, and the second edge 1132 includes a second bent portion 1132B bent from the second conductive region 112 to the channel region 113, so that both edges of the channel region can be bent to the center of the channel region.

In some examples, as illustrated by FIG. 6, the first bent portion 1131B and the second bent portion 1132B are overlapped in the first direction X, so that the first bent portion 1131B and the second bent portion 1132B can form the narrowed portion of the channel region together. Of course, the embodiments of the present disclosure include but are not limited thereto, and the first bent portion and the second bent portion can also be staggered in the first direction, thus forming two narrowed portions.

In some examples, as illustrated by FIG. 6, the first bent portion 1131B and the second bent portion 1132B include oblique lines, such as a V-shape formed by two oblique lines; the oblique line is a straight line with an included angle of less than 90 degrees with the first direction X. Of course, the embodiments of the present disclosure include but are not limited thereto, and the first bent portion and the second bent portion may also include an arc line or a step-shaped line.

In some examples, as illustrated by FIG. 6, the channel region 113 further includes a main portion 113A connected with the narrowed portion 113B, and the size of the main portion 113A in the first direction X is greater than the maximum size of the narrowed portion 113B in the first direction X. In this case, the first edge 1131 includes a straight line connected with the first bent portion 1131B, and the second edge 1132 also includes a straight line connected with the second bent portion 1132B. The straight line may be a straight line extending along the second direction Y.

In some examples, as illustrated by FIG. 6, the first edge 1131 includes two straight lines connected with the first bent portion 1131B and located on both sides of the first bent portion 1131B; the second edge 1132 includes two straight lines connected with the second bent portion 1132B and located on both sides of the second bent portion 1132B.

In some examples, as illustrated by FIG. 6, the first conductive region 111 may be a source region, and the second conductive region 112 may be a drain region. Alternatively, the first conductive region 111 may be a drain region, and the second conductive region 112 may be a source region.

In some examples, the first conductive region 111 and the second conductive region 112 may be conductive by a doping method. Of course, the embodiments of the present disclosure include but are not limited thereto, and the abovementioned first conductive region and second conductive region can also be conductive in other methods.

In some examples, as illustrated by FIG. 6 and FIG. 7, the thin film transistor 100 further includes a second gate insulating layer 140 and a second gate electrode 150; the second gate insulating layer 140 is located on a second side of the active layer 110, and the second side of the active layer 110 and the abovementioned first side of the active layer 110 may be opposite sides in the direction perpendicular to the main surface of the active layer 110, such as upper and lower sides; the second gate electrode 150 is located on a side of the second gate insulating layer 140 away from the active layer 110, and an orthographic projection of the second gate electrode 150 on the active layer 110 completely covers an orthographic projection of the first gate electrode 130 on the active layer 110.

In some examples, as illustrated by FIG. 6, the first gate electrode 130 and the second gate electrode 150 may be electrically connected through a first connection electrode 191.

In the thin film transistor provided by this example, by connecting the second gate electrode and the first gate electrode, and the orthographic projection of the second gate electrode on the active layer completely covers the orthographic projection of the first gate electrode on the active layer, the thin film transistor can be formed into a double-gate structure, so that the on-state current Ion can be increased, for example, to 3-5 times that of a thin film transistor without the second gate electrode. Therefore, the thin film transistor can greatly improve the charging and discharging efficiency; combined with the design of the abovementioned special-shaped channel region, the thin film transistor can not only meet the requirements of high refresh rate and high resolution products for on-state current, but also increase the subthreshold swing, so as to make the thin film transistor insensitive to the gate voltage, significantly improve the display quality and ameliorate the Mura defect. In addition, by making the orthographic projection of the second gate electrode on the active layer completely cover the orthographic projection of the first gate electrode on the active layer, the thin film transistor can avoid the characteristic deviation caused by the second gate electrode retracting within the orthographic projection of the first gate electrode.

In some examples, as illustrated by FIG. 6, the channel region 113 includes a first edge 1131 and a second edge 1132, the first edge 1131 is in contact with the first conductive region 111 and the second edge 1132 is in contact with the second conductive region 112; the shortest distance between the first edge 1131 and the edge of the orthographic projection of the second gate electrode 150 on the active layer 110 is greater than 1.0 micron. The shortest distance between the second edge 1132 and the edge of the orthographic projection of the second gate electrode 150 on the active layer 110 is greater than 1.0 micron. Therefore, by setting the above g value, the thin film transistor can better avoid the characteristic deviation, and can also avoid the characteristic difference between different thin film transistors in the mass production process caused by process errors.

In some examples, as illustrated by FIG. 6, the first conductive region 111 includes a first protrusion portion 111B connected with the first bent portion 1131B, and the second conductive region 112 includes a second protrusion portion 112B connected with the second bent portion 1132B. Both the first protrusion portion 111B and the second protrusion portion 112B are conductive regions.

In some examples, as illustrated by FIG. 6, the first protrusion portion 111B and the second protrusion portion 112B are mirror-image symmetrical with respect to the center line of the channel region 113 extending in the second direction Y. Therefore, the thin film transistor can make the first conductive region and the second conductive region have better symmetry.

In some examples, as illustrated by FIG. 6, the shape of the orthographic projection of the first gate electrode 130 on the active layer 110 is the same as the shape of the channel region 113C. Therefore, the first gate electrode can be used as a mask to perform a conductive process (such as doping process) on the active layer to form the abovementioned special-shaped channel region.

In some examples, as illustrated by FIG. 6, the first gate electrode 130 may include a gate main portion corresponding to the main portion 113A of the channel region 113 and a gate narrowed portion corresponding to the narrowed portion 113B of the channel region 113. Because the shape of the orthographic projection of the first gate electrode on the active layer is the same as the shape of the channel region, the positional relationship between the gate main portion and the gate narrowed portion, and the shapes and sizes of the gate main portion and the gate narrowed portion themselves can be referred to the relevant descriptions and definitions of the main portion and narrowed portion of the channel region, and the repeated portions are omitted in the embodiments of the present disclosure.

In some examples, as illustrated by FIG. 6, the thin film transistor 100 further includes a first electrode 181 and a second electrode 182; the first electrode 181 is electrically connected with the first conductive region 111; the second electrode 182 is electrically connected with the second conductive region 112. The first electrode 181 may be a source electrode and the second electrode may be a drain electrode. Alternatively, the first electrode 181 may be a drain electrode and the second electrode 182 may be a source electrode.

In some examples, as illustrated by FIG. 6 and FIG. 7, a passivation layer 170 is provided between a layer where the first electrode 181 and the second electrode 182 are located and the active layer 110. The first electrode 181 is electrically connected with the first conductive region 111 of the active layer 110 through a first via 171 penetrating through the passivation layer 170, and the second electrode 182 is connected with the second conductive region 112 of the active layer 110 through a second via 172 penetrating through the passivation layer 170.

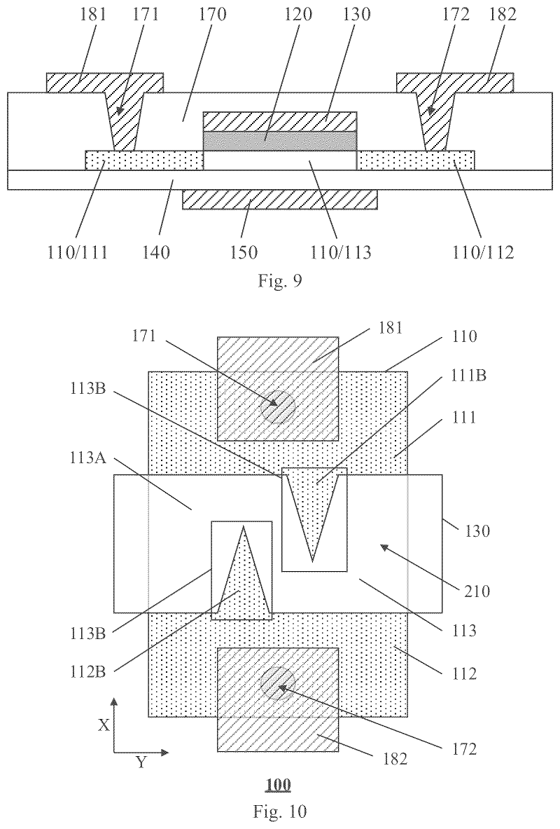

FIG. 8 is a schematic plan view of another thin film transistor provided by an embodiment of the present disclosure; FIG. 9 is a schematic cross-sectional view of another thin film transistor provided by an embodiment of the present disclosure.

As illustrated by FIG. 8 and FIG. 9, the thin film transistor 100 includes an active layer 110, a first gate insulating layer 120, a first gate electrode 130, a second gate insulating layer 140, a second gate electrode 150, a first electrode 181 and a second electrode 182. The active layer 110 includes a channel region 113 and a first conductive region 111 and a second conductive region 112 separated by the channel region 113, and the conductivity of the first conductive region 111 and the conductivity of the second conductive region 112 are greater than the conductivity of the channel region 113; the first gate insulating layer 120 is located on a first side of the active layer 110, and the second gate insulating layer 140 is located on a second side of the active layer 110, the first side and the second side are opposite sides in a direction perpendicular to the main surface of the active layer 110.

As illustrated by FIG. 8 and FIG. 9, the first gate electrode 130 is located on a side of the first gate insulating layer 120 away from the active layer 110, and the second gate electrode 150 is located on a side of the second gate insulating layer 120 away from the active layer 110. At least part of the first conductive region 111, at least part of the channel region 113 and at least part of the second conductive region 112 are arranged in the first direction X; the first electrode 181 is electrically connected with the first conductive region 111, and the second electrode 182 is electrically connected with the second conductive region 112. For example, the first conductive region 111 may be a source region, the first electrode 181 may be a source electrode, the second conductive region 112 may be a drain region, and the second electrode may be a drain electrode; alternatively, the first conductive region 111 may be a drain region, the first electrode 181 may be a drain electrode, the second conductive region 112 may be a source region, and the second electrode 182 may be a source electrode.

As illustrated by FIG. 8 and FIG. 9, the first direction X can also be regarded as a length direction of the channel region 113. The channel region 113 includes a narrowed portion 113B, and an average size of the narrowed portion 113B in the first direction X is smaller than an average size of the channel region 113 in the first direction X, that is, an average channel length of the narrowed portion 113B is smaller than an average channel length of the whole channel region 113.

In the thin film transistor provided by the embodiments of the present disclosure, because the channel region includes the narrowed portion, and the average size of the narrowed portion in the first direction is smaller than the average size of the channel in the first direction, the channel region has a smaller channel length in the narrowed portion and a larger channel length in other portions (which can also be called the main portion). In this case, taking the case that the channel region of the thin film transistor is an N-type channel as an example, when the gate voltage on the first gate electrode is not enough to turn on other portions of the channel region and only the narrowed portion can be turned on, the thin film transistor can generate a pilot effect similar to the Hump Effect, the narrowed portion is turned on, and the output current of the thin film transistor is mainly on the narrowed portion; when the gate voltage on the first gate electrode is increased to turn on other portions of the channel region, other portions can also be turned on, and the output current of the thin film transistor is mainly on other portions. Therefore, by designing a special-shaped channel region including the narrowed portion, the thin film transistor makes the channel lengths of different regions of the channel region different, which makes the thin film transistor produce a pilot effect similar to the Hump Effect, and increases the subthreshold swing of the thin film transistor, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated. For the principle of how increasing the subthreshold swing of the thin film transistor can increase the data voltage range (Data Range), please refer to the related descriptions in FIG. 2 and FIG. 3, which will not be repeated here.

In some examples, as illustrated by FIG. 8, the first direction X and the second direction Y are perpendicular to each other. Of course, the embodiments of the present disclosure include, but are not limited thereto, and the first direction and the second direction may also intersect and form an included angle not equal to 90 degrees.

In some examples, as illustrated by FIG. 8, the first electrode 181 is electrically connected with the second gate electrode 150, for example, through a via connection structure. Therefore, on the basis of the special-shaped channel region, the thin film transistor can further increase the subthreshold swing by connecting the first electrode with the second gate electrode, thereby further improving the data voltage range (Data Range) of the thin film transistor, and further making the driving current provided by the driving transistor insensitive to voltage fluctuation.

In some examples, as illustrated by FIG. 8, the second gate electrode 150 includes an extension portion, and the first electrode 181 is connected with the extension portion of the second gate electrode 150 through a via connection structure.

In some examples, as illustrated by FIG. 8, the orthographic projection of the second gate electrode 150 on the active layer 110 completely covers the orthographic projection of the first gate electrode 130 on the active layer 110. Therefore, the thin film transistor can avoid the characteristic deviation caused by the second gate retracting within the orthographic projection of the first gate electrode.

In some examples, as illustrated by FIG. 8, the channel region 113 includes a first edge 1131 and a second edge 1132, the first edge 1131 is in contact with the first conductive region 111 and the second edge 1132 is in contact with the second conductive region 112; the shortest distance between the first edge 1131 and the edge of the orthographic projection of the second gate electrode 150 on the active layer 110 is greater than 1.0 micron. The shortest distance between the second edge 1132 and the edge of the orthographic projection of the second gate electrode 150 on the active layer 110 is greater than 1.0 micron. Therefore, by setting the above g value, the thin film transistor can better avoid the characteristic deviation, and can also avoid the characteristic difference between different thin film transistors in the mass production process caused by process errors.

In some examples, as illustrated by FIG. 8, the first edge 1131 includes a first bent portion 1131B bent from the first conductive region 111 to the channel region 113, and the second edge 1132 includes a second bent portion 1132B bent from the second conductive region 112 to the channel region 113, so that both edges of the channel region can be bent to the center of the channel region.

In some examples, as illustrated by FIG. 8, the first bent portion 1131B and the second bent portion 1132B are overlapped in the first direction X, so that the first bent portion 1131B and the second bent portion 1132B can form the narrowed portion of the channel region together. Of course, the embodiments of the present disclosure include but are not limited thereto, and the first bent portion and the second bent portion can also be staggered in the first direction, thus forming two narrowed portions.

In some examples, as illustrated by FIG. 8, the first bent portion 1131B and the second bent portion 1132B include oblique lines, such as a V-shape formed by two oblique lines; the oblique line is a straight line with an included angle of less than 90 degrees with the first direction X. Of course, the embodiments of the present disclosure include but are not limited thereto, and the first bent portion and the second bent portion may also include an arc line or a step-shaped line.

In some examples, as illustrated by FIG. 8, the channel region 113 further includes a main portion 113A connected with the narrowed portion 113B, and the size of the main portion 113A in the first direction X is greater than the maximum size of the narrowed portion 113B in the first direction X. In this case, the first edge 1131 includes a straight line connected with the first bent portion 1131B, and the second edge 1132 also includes a straight line connected with the second bent portion 1132B. The straight line may be a straight line extending along the second direction Y.

In some examples, as illustrated by FIG. 8, the first edge 1131 includes two straight lines connected with the first bent portion 1131B and located on both sides of the first bent portion 1131B; the second edge 1132 includes two straight lines connected with the second bent portion 1132B and located on both sides of the second bent portion 1132B.

In some examples, as illustrated by FIG. 8, the first conductive region 111 may be a source region, and the second conductive region 112 may be a drain region. Alternatively, the first conductive region 111 may be a drain region, and the second conductive region 112 may be a source region.

In some examples, the first conductive region 111 and the second conductive region 112 may be conductive by a doping method. Of course, the embodiments of the present disclosure include but are not limited thereto, and the abovementioned first conductive region and second conductive region can also be conductive in other methods.

In some examples, as illustrated by FIG. 8, the first conductive region 111 includes a first protrusion portion 111B connected with the first bent portion 1131B, and the second conductive region 112 includes a second protrusion portion 112B connected with the second bent portion 1132B. Both the first protrusion portion 111B and the second protrusion portion 112B are conductive regions.

In some examples, as illustrated by FIG. 8, the first protrusion portion 111B and the second protrusion portion 112B are mirror-image symmetrical with respect to the center line of the channel region 113 extending in the second direction Y. Therefore, the thin film transistor can make the first conductive region and the second conductive region have better symmetry.

In some examples, as illustrated by FIG. 8, the shape of the orthographic projection of the first gate electrode 130 on the active layer 110 is the same as the shape of the channel region 113C. Therefore, the first gate electrode can be used as a mask to perform a conductive process (such as a doping process) on the active layer to form the abovementioned special-shaped channel region.

In some examples, as illustrated by FIG. 8, the first gate electrode 130 may include a gate main portion corresponding to the main portion 113A of the channel region 113 and a gate narrowed portion corresponding to the narrowed portion 113B of the channel region 113. Because the shape of the orthographic projection of the first gate electrode on the active layer is the same as the shape of the channel region, the positional relationship between the gate main portion and the gate narrowed portion, and the shapes and sizes of the gate main portion and the gate narrowed portion themselves can be referred to the relevant descriptions and definitions of the main portion and narrowed portion of the channel region, and the repeated portions are omitted in the embodiments of the present disclosure.

In some examples, as illustrated by FIG. 8 and FIG. 9, a passivation layer 170 is provided between a layer where the first electrode 181 and the second electrode 182 are located and the active layer 110. The first electrode 181 is electrically connected with the first conductive region 111 of the active layer 110 through a first via 171 penetrating through the passivation layer 170, and the second electrode 182 is connected with the second conductive region 112 of the active layer 110 through a second via 172 penetrating through the passivation layer 170.

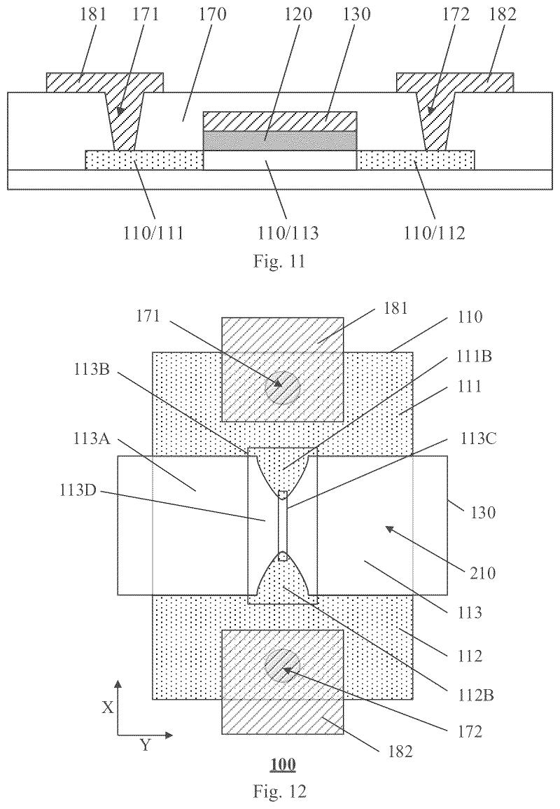

FIG. 10 is a schematic plan view of another thin film transistor provided by an embodiment of the present disclosure; FIG. 11 is a schematic cross-sectional view of another thin film transistor provided by an embodiment of the present disclosure.

As illustrated by FIG. 10 and FIG. 11, the thin film transistor 100 includes an active layer 110, a first gate insulating layer 120 and a first gate electrode 130; the active layer 110 includes a channel region 113 and a first conductive region 111 and a second conductive region 112 separated by the channel region 113. The first gate insulating layer 120 is located on a first side of the active layer 110, the first side is a side in a direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as a length direction of the channel region 113. The channel region 113 includes a plurality of narrowed portions 113B, which are arranged in a second direction Y intersecting with the first direction X, and an average size of each narrowed portion 113B in the first direction X is smaller than an average size of the channel region 113 in the first direction X, that is, an average channel length of the narrowed portion 113B is smaller than an average channel length of the whole channel region 113.

In the abovementioned thin film transistor, the channel region includes a plurality of narrowed portions arranged in the second direction Y intersecting with the first direction X, and each narrowed portion can generate a piolet effect similar to a Hump Effect. Therefore, by designing a special-shaped channel region including a plurality of narrowed portions, the thin film transistor makes the channel lengths of different regions of the channel region different, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated.

In some examples, the first direction X and the second direction Y are perpendicular to each other. Of course, the embodiments of the present disclosure include but are not limited thereto, and the first direction X and the second direction Y may cross each other at a certain angle, but are not strictly perpendicular to each other.

In some examples, the number of narrowed portions included in the channel region can be set according to the actual situation, and the embodiments of the present disclosure are not limited in this aspect.

In some examples, as illustrated by FIG. 10, the channel region 113 includes a main portion 113A and a narrowed portion 113B, and an average size of the narrowed portion 113B in the first direction X is smaller than an average size of the main portion 113A in the first direction X; the plurality of narrowed portions 113B are staggered in the first direction X.

In some examples, as illustrated by FIG. 10, the channel region 113 includes two narrowed portions 113B, the first conductive region 111 is located on a first side of the channel region 113, and the second conductive region 112 is located on a second side of the channel region 113; one of the two narrowed portions 113B included in the channel region 113 narrows from the first side to a center line of the channel region 113 extending in the second direction Y intersecting with the first direction X, and the other one of the two narrowed portions 113B included in the channel region 113 narrows from the second side to the center line of the channel region 113 extending in the second direction Y intersecting with the first direction X.

In some examples, as illustrated by FIG. 10, the first conductive region 111 includes a first protrusion portion 111B connected with one of the two narrowed portions 113B included in the channel region 113, and the second conductive region 112 includes a second protrusion portion 112B connected with the other one of the two narrowed portions 113B included in the channel region 113. Both the first protrusion portion 111B and the second protrusion portion 112B are conductive regions.

For example, as illustrated by FIG. 10, the first conductive region 111 is a source region and the second conductive region 112 is a drain region; alternatively, the first conductive region 111 is a drain region and the second conductive region 112 is a source region.

In some examples, as illustrated by FIG. 10, the thin film transistor 100 further includes a first electrode 181 and a second electrode 182; the first electrode 181 is electrically connected with the first conductive region 111; and the second electrode 182 is electrically connected with the second conductive region 112. The first electrode 181 may be a source electrode and the second electrode may be a drain electrode. Alternatively, the first electrode 181 may be a drain electrode and the second electrode 182 may be a source electrode.

In some examples, as illustrated by FIG. 10 and FIG. 11, a passivation layer 170 is provided between a layer where the first electrode 181 and the second electrode 182 are located and the active layer 110. The first electrode 181 is electrically connected with the first conductive region 111 of the active layer 110 through a first via 171 penetrating through the passivation layer 170, and the second electrode 182 is connected with the second conductive region 111 of the active layer 110 through a second via 172 penetrating through the passivation layer 170.

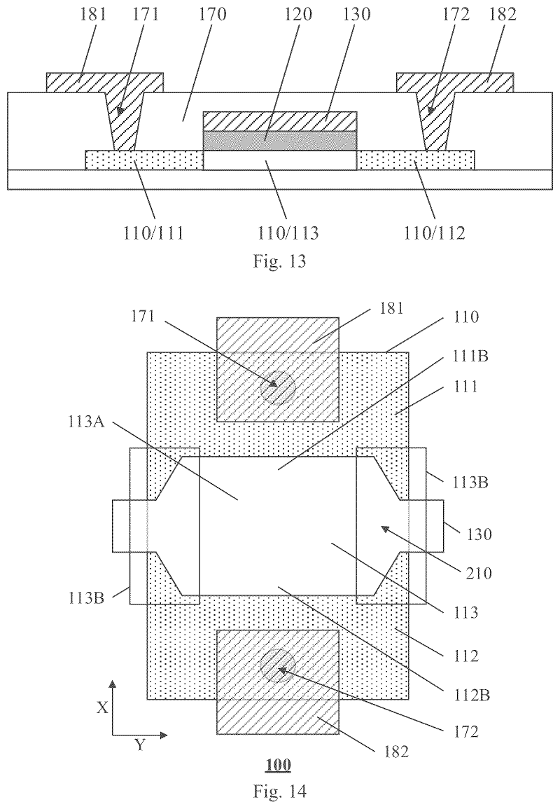

FIG. 12 is a schematic plan view of another thin film transistor provided by an embodiment of the present disclosure; FIG. 13 is a schematic cross-sectional view of another thin film transistor provided by an embodiment of the present disclosure.

As illustrated by FIG. 12 and FIG. 13, the thin film transistor 100 includes an active layer 110, a first gate insulating layer 120 and a first gate electrode 130; the active layer 110 includes a channel region 113 and a first conductive region 111 and a second conductive region 112 separated by the channel region 113. The first gate insulating layer 120 is located on a first side of the active layer 110, the first side is a side in the direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as a length direction of the channel region 113. The channel region 113 includes a main portion 113A and a narrowed portion 113B. The average size of the narrowed portion 113B in the first direction X is smaller than an average size of the main portion 113A in the first direction X, that is, an average channel length of the narrowed portion 113B is smaller than an average channel length of the whole channel region 113.

As illustrated by FIG. 12 and FIG. 13, the narrowed portion 113B includes an extremely narrowed portion 113C, and the size of the extremely narrowed portion 113C in the first direction X is the smallest size of the narrowed portion 113B in the first direction X; the narrowed portion 113B is connected with the main portion 113A, and the size of the narrowed portion 113B in the first direction X gradually decreases from the connection position between the narrowed portion 113B and the main portion 113A to the extremely narrowed portion 113C. The narrowed portion 113B includes an edge extending from the main portion 113A to the extremely narrowed portion 113C, and the shape of the edge includes an arc line or a curved line. That is to say, the size of the narrowed portion in the first direction X can be gradually reduced by setting the arc-shaped or curve-shaped edge. It should be noted that although the arc line or curved line shown in FIG. 12 is an arc line or curved line concave to the channel region, the embodiments of the present disclosure include but are not limited thereto, and the above edge may also be an arc line or curved line protruding from the channel region.

In the abovementioned thin film transistor, the narrowed portion with arc-shaped or curve-shaped edge can also generate a piolet effect similar to the Hump Effect. Therefore, by designing the thin film transistor to include the special-shaped channel region, the channel lengths of different regions of the channel region are different, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated.

In some examples, as illustrated by FIG. 12, the first conductive region 111 includes a first protrusion portion 111B connected with the narrowed portion 113B, and the second conductive region 112 includes a second protrusion portion 112B connected with the narrowed portion 113B. Both the first protrusion portion 111B and the second protrusion portion 112B are conductive regions. The shapes of the first protrusion portion 111B and the second protrusion portion 112B are complementary to the shape of the narrowed portion 113B.

In some examples, as illustrated by FIG. 12, the first conductive region 111 is a source region and the second conductive region 112 is a drain region; alternatively, the first conductive region 111 is a drain region and the second conductive region 112 is a source region.

In some examples, as illustrated by FIG. 12, the thin film transistor 100 further includes a first electrode 181 and a second electrode 182; the first electrode 181 is electrically connected with the first conductive region 111, and the second electrode 182 is electrically connected with the second conductive region 112. The first electrode 181 may be a source electrode and the second electrode may be a drain electrode. Alternatively, the first electrode 181 may be a drain electrode and the second electrode 182 may be a source electrode.

In some examples, as illustrated by FIG. 12 and FIG. 13, a passivation layer 170 is provided between the layer where the first electrode 181 and the second electrode 182 are located and the active layer 110. The first electrode 181 is electrically connected with the first conductive region 111 of the active layer 110 through a first via 171 penetrating through the passivation layer 170, and the second electrode 182 is connected with the second conductive region 111 of the active layer 110 through a second via 172 penetrating through the passivation layer 170.

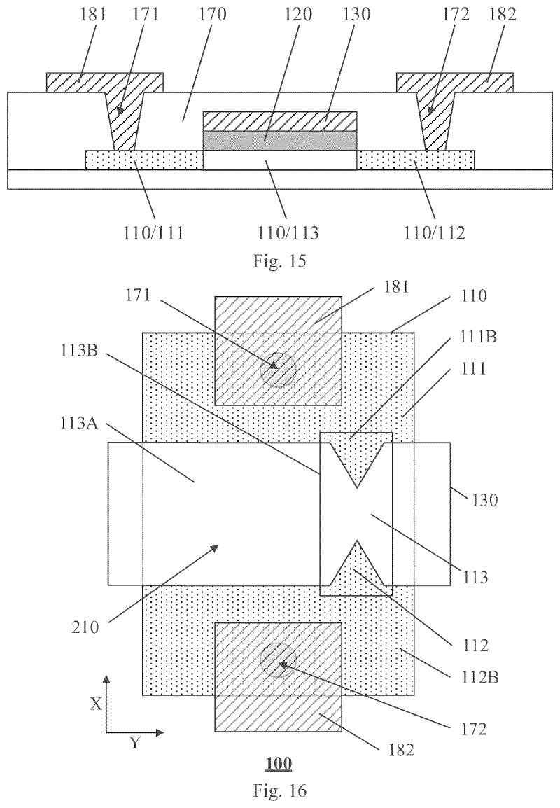

FIG. 14 is a schematic plan view of another thin film transistor provided by an embodiment of the present disclosure; FIG. 15 is a schematic cross-sectional view of another thin film transistor provided by an embodiment of the present disclosure.

As illustrated by FIG. 14 and FIG. 15, the thin film transistor 100 includes an active layer 110, a first gate insulating layer 120 and a first gate electrode 130; the active layer 110 includes a channel region 113 and a first conductive region 111 and a second conductive region 112 separated by the channel region 113. The first gate insulating layer 120 is located on a first side of the active layer 110, the first side is one side in the direction perpendicular to the main surface of the active layer 110. The first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as the length direction of the channel region 113.

As illustrated by FIG. 14 and FIG. 15, the channel region 113 includes a main portion 113A and narrowed portions 113B located on both sides of the main portion 113A. The average size of the narrowed portion 113B in the first direction X is smaller than the average size of the main portion 113A in the first direction X, that is, the average channel length of the narrowed portion 113B is smaller than the average channel length of the whole channel region 113.

In the abovementioned thin film transistor, the narrowed portions located on both sides of the main portion can also generate a piolet effect similar to the Hump Effect. Therefore, the thin film transistor is designed to include the special-shaped channel region, so that the channel lengths of different regions of the channel region are different, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated.

In some examples, as illustrated by FIG. 14, the first conductive region 111 and the second conductive region 112 are arranged opposite to each other and spaced part and define a connection region 210 between the first conductive region 111 and the second conductive region 112, and the narrowed portion 113B is located in the connection region 210.

In some examples, as illustrated by FIG. 14, the connection region 210 includes a center line extending along the first direction X, and the narrowed portions 113B located on both sides of the main portion 113A are not overlapped with the center line.

In some examples, as illustrated by FIG. 14, the first conductive region 111 is a source region and the second conductive region 112 is a drain region; alternatively, the first conductive region 111 is a drain region and the second conductive region 112 is a source region.

In some examples, as illustrated by FIG. 14 and FIG. 15, the thin film transistor 100 further includes a first electrode 181 and a second electrode 182; the first electrode 181 is electrically connected with the first conductive region 111; and the second electrode 182 is electrically connected with the second conductive region 112. The first electrode 181 may be a source electrode and the second electrode may be a drain electrode. Alternatively, the first electrode 181 may be a drain electrode and the second electrode 182 may be a source electrode.

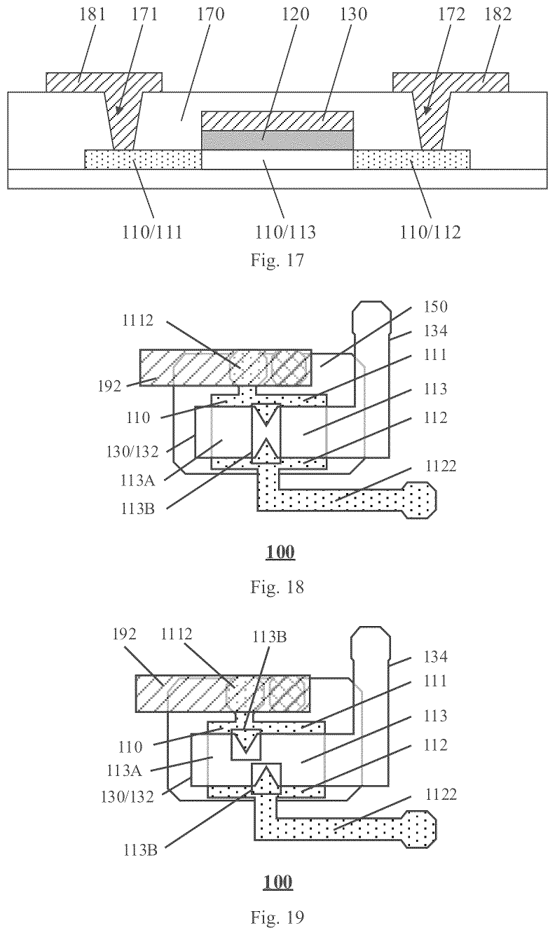

FIG. 16 is a schematic plan view of another thin film transistor provided by an embodiment of the present disclosure; FIG. 17 is a schematic cross-sectional view of another thin film transistor provided by an embodiment of the present disclosure.

As illustrated by FIG. 16 and FIG. 17, the thin film transistor 100 includes an active layer 110, a first gate insulating layer 120 and a first gate electrode 130; the active layer 110 includes a channel region 113 and a first conductive region 111 and a second conductive region 112 separated by the channel region 113, and the conductivity of the first conductive region 111 and the conductivity of the second conductive region 112 are greater than the conductivity of the channel region 113. The first gate insulating layer 120 is located on a first side of the active layer 110, the first side is a side in the direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as the length direction of the channel region 113. The channel region 113 includes a narrowed portion 113B, and an average size of the narrowed portion 113B in the first direction X is smaller than an average size of the channel region 113 in the first direction X, that is, an average channel length of the narrowed portion 113B is smaller than an average channel length of the whole channel region 113.

In the thin film transistor provided by the embodiments of the present disclosure, because the channel region includes the narrowed portion, and the average size of the narrowed portion in the first direction is smaller than the average size of the channel in the first direction, the channel region has a smaller channel length in the narrowed portion and a larger channel length in other portions (which can also be called the main portion). In this case, taking the channel region of the thin film transistor being an N-type channel region as an example, when the gate voltage on the first gate electrode is not enough to turn on other portions of the channel region and only the narrowed portion can be turned on, the thin film transistor can generate a pilot effect similar to the Hump Effect, the narrowed portion is turned on, and the output current of the thin film transistor is mainly on the narrowed portion; when the gate voltage on the first gate electrode is increased to turn on other portions of the channel region, other portions can also be turned on, and the output current of the thin film transistor is mainly on other portions. Therefore, by designing a special-shaped channel region including the narrowed portion, the channel lengths of different regions of the channel region are different, which makes the thin film transistor produce a pilot effect similar to the Hump Effect, and increases the subthreshold swing of the thin film transistor, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated. For the principle of how increasing the subthreshold swing of the thin film transistor can increase the data voltage range (Data Range), please refer to the related descriptions in FIG. 2 and FIG. 3, which will not be repeated here.

In some examples, as illustrated by FIG. 16, the first direction X and the second direction Y are perpendicular to each other. Of course, the embodiments of the present disclosure include, but are not limited thereto, and the first direction and the second direction may also intersect and form an included angle not equal to 90 degrees.

In some examples, as illustrated by FIG. 16, the first conductive region 111 and the second conductive region 112 are arranged opposite to each other and spaced part and define a connection region 210 between the first conductive region 111 and the second conductive region 112, and the narrowed portion 113B is located in the connection region 210. The connection region 210 is overlapped with the first conductive region 111 and the second conductive region 112 in the first direction X. Therefore, the narrowed portion can better produce the abovementioned piolet effect.

In some examples, as illustrated by FIG. 16, unlike the thin film transistor shown in FIG. 2, the connection region 210 includes a center line extending in the first direction X, and the narrowed portion 113B is staggered from the center line, that is, the narrowed portion 113B is not overlapped with the center line. FIG. 18 is a schematic plan view of another thin film transistor provided by an embodiment of the present disclosure. As illustrated by FIG. 18, the thin film transistor 100 includes an active layer 110, a first gate insulating layer (not shown) and a first gate electrode 130; the active layer 110 includes a channel region 113 and a first conductive region 111 and a second conductive region 112 separated by the channel region 113. The first gate insulating layer 120 is located on a first side of the active layer 110, the first side is a side in a direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as the length direction of the channel region 113.

As illustrated by FIG. 18, a planar shape of the channel region 113 is generally rectangular, and the planar shape of the gate electrode 130 is generally L-shaped; the gate electrode 130 includes a first rectangular portion 132 and a second rectangular portion 134, and the first rectangular portion of the gate electrode 130 is overlapped with the channel region 113. The channel region 113 further includes a first extension portion 1112 connected with the first conductive region 111 and a second extension portion 1122 connected with the second conductive region 112. The first extension portion 1112 and the second extension portion 1122 may be connected with other conductive structures.

As illustrated by FIG. 18, the channel region 113 includes a main portion 113A and a narrowed portion 113B. The average size of the narrowed portion 113B in the first direction X is smaller than the average size of the main portion 113A in the first direction X, that is, the average channel length of the narrowed portion 113B is smaller than the average channel length of the whole channel region 113.

In the abovementioned thin film transistor, the narrowed portion can produce a piolet effect similar to the Hump Effect; therefore, by designing the thin film transistor to include the special-shaped channel region, the channel lengths of different regions of the channel region are different, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated.

In some examples, as illustrated by FIG. 18, the thin film transistor 100 further includes a second gate electrode 150, which is located on a side of the active layer 110 away from the first gate electrode 130 and is insulated from the active layer 110; an orthographic projection of the second gate electrode 150 on the active layer 110 completely covers an orthographic projection of the first gate electrode 130 on the active layer 110, thus forming a thin film transistor with a double gate structure.

In some examples, as illustrated by FIG. 18, the first conductive region 111 is electrically connected with the second gate electrode 150. For example, the first extension portion 1112 of the channel region 113 is electrically connected with the second gate electrode 150 through the third connection electrode 191. Therefore, on the basis of the special-shaped channel region, the thin film transistor can further increase the subthreshold swing by connecting the first conductive region with the second gate electrode, thereby further improving the data voltage range (Data Range) of the thin film transistor, and further making the driving current provided by the driving transistor insensitive to voltage fluctuation.

FIG. 19 is a schematic plan view of another thin film transistor provided by an embodiment of the present disclosure. As illustrated by FIG. 19, the thin film transistor 100 includes an active layer 110, a first gate insulating layer (not shown) and a first gate electrode 130; the active layer 110 includes a channel region 113 and a first conductive region 111 and a second conductive region 112 separated by the channel region 113. The first gate insulating layer 120 is located on a first side of the active layer 110, the first side is a side in the direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as a length direction of the channel region 113.

As illustrated by FIG. 19, the planar shape of the channel region 113 is generally rectangular, and the planar shape of the gate electrode 130 is generally L-shaped; the gate electrode 130 includes a first rectangular portion 132 and a second rectangular portion 134, and the first rectangular portion of the gate electrode 130 overlaps with the channel region 113. The channel region 113 further includes a first extension portion 1112 connected with the first conductive region 111 and a second extension portion 1122 connected with the second conductive region 112. The first extension portion 1112 and the second extension portion 1122 may be connected with other conductive structures.

As illustrated by FIG. 19, the channel region 113 includes a main portion 113A and two narrowed portions 113B. A virtual straight line extending in the first direction passes through one of the two narrowed portions 113B and a position where the first extension portion 1112 and the first conductive region 111 are connected, an another virtual straight line extending in the first direction passes through the other one of the two narrowed portions 113B and a position where the second extension portion 1122 and the second conductive region 112 are connected, so as to better enable the thin film transistor to generate a pilot effect similar to the Hump Effect.

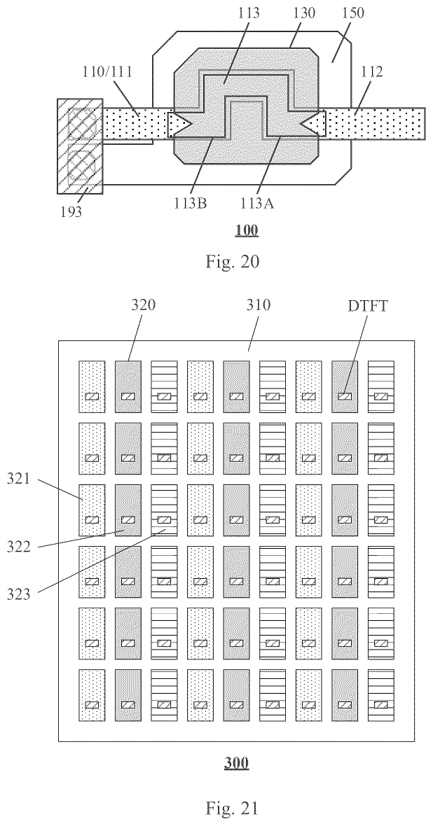

FIG. 20 is a schematic plan view of another thin film transistor provided by an embodiment of the present disclosure. As illustrated by FIG. 20, the thin film transistor 100 includes an active layer 110, a first gate insulating layer (not shown) and a first gate electrode 130; the active layer 110 includes a channel region 113 and a first conductive region 111 and a second conductive region 112 separated by the channel region 113. The first gate insulating layer 120 is located on a first side of the active layer 110, the first side is a side in the direction perpendicular to the main surface of the active layer 110; the first gate electrode 130 is located on a side of the first gate insulating layer 120 away from the active layer 110. At least part of the first conductive region 111, at least part of the channel region 113 and at least part of the second conductive region 112 are arranged in the first direction X; in this case, the first direction X can also be regarded as the length direction of the channel region 113.

As illustrated by FIG. 20, the planar shape of the channel region 113 is approximately Ω-shaped, and the planar shape of the gate electrode is approximately rectangular; the channel region 113 includes a main portion 113A and a narrowed portion 113B. An average size of the narrowed portion 113B in the first direction X is smaller than an average size of the main portion 113A in the first direction X, that is, an average channel length of the narrowed portion 113B is smaller than an average channel length of the whole channel region 113.

In the abovementioned thin film transistor, the narrowed portion can produce a piolet effect similar to the Hump Effect; therefore, by designing the thin film transistor to include the special-shaped channel region, the channel lengths of different regions of the channel region are different, so that the thin film transistor generates a pilot effect similar to the Hump Effect, and the subthreshold swing of the thin film transistor is increased, thereby improving the data voltage range (Data Range) of the thin film transistor, and further making the driving current provided by the driving transistor insensitive to voltage fluctuation. When a display device adopts the thin film transistor as the driving transistor, the display quality can be significantly improved and the Mura defect can be ameliorated.

In some examples, as illustrated by FIG. 20, the thin film transistor 100 further includes a second gate electrode 150, which is located on a side of the active layer 110 away from the first gate electrode 130 and is insulated from the active layer 110; an orthographic projection of the second gate electrode 150 on the active layer 110 completely covers an orthographic projection of the first gate electrode 130 on the active layer 110, thus forming a thin film transistor with a double gate structure.

In some examples, as illustrated by FIG. 20, the first conductive region 111 is electrically connected with the second gate electrode 150. For example, the first conductive region 111 is electrically connected with the second gate electrode 150 through the third connection electrode 193. Therefore, on the basis of the special-shaped channel region, the thin film transistor can further increase the subthreshold swing by connecting the first conductive region with the second gate electrode, thereby further improving the data voltage range (Data Range) of the thin film transistor, and further making the driving current provided by the driving transistor insensitive to voltage fluctuation.

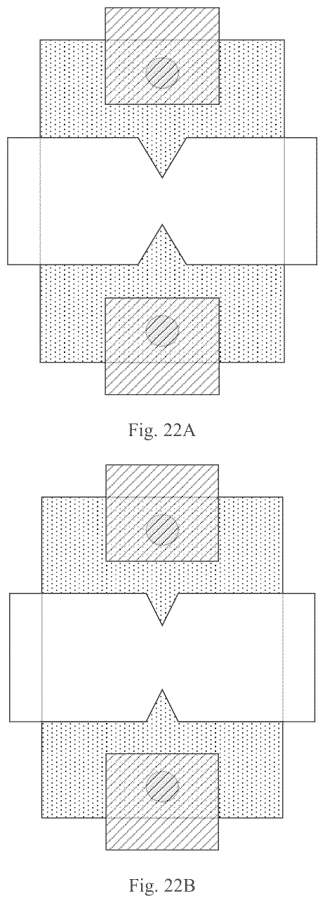

At least one embodiment of the present disclosure further provides an array substrate. FIG. 21 is a schematic plan view of an array substrate provided by an embodiment of the present disclosure. As illustrated by FIG. 21, the array substrate 300 includes a base substrate 310 and a thin film transistor 100 according to any example. Therefore, the array substrate can use the thin film transistor with a large subthreshold swing as the driving transistor, so that the driving current provided by the driving transistor is insensitive to voltage fluctuation, thereby reducing the sensitivity of the luminous brightness of the sub-pixel to voltage fluctuation, thus significantly improving the display quality and ameliorating the Mura defect.

In some examples, as illustrated by FIG. 21, the array substrate 300 further includes a plurality of pixel driving circuits 320 arranged in an array, each pixel driving circuit 320 includes a driving thin film transistor DTFT, and the driving thin film transistor DTFT adopts the abovementioned thin film transistor 100. Therefore, the array substrate can use the thin film transistor with a large subthreshold swing as the driving transistor, so that the driving current provided by the driving transistor is insensitive to voltage fluctuation, thereby reducing the sensitivity of the luminous brightness of the sub-pixel to voltage fluctuation, thus significantly improving the display quality and ameliorating the Mura defect.

In some examples, as illustrated by FIG. 21, the plurality of pixel driving circuits 320 include a first pixel driving circuit 321, a second pixel driving circuit 322 and a third pixel driving circuit 323; the first pixel driving circuit 321 is configured to drive a first sub-pixel to emit light of a first color; the second pixel driving circuit 322 is configured to drive a second sub-pixel to emit light of a second color; the third pixel driving circuit 323 is configured to drive a third sub-pixel to emit light of a third color. A size of the narrowed portion of the driving thin film transistor DTFT of the first pixel driving circuit 321, a size of the narrowed portion of the driving thin film transistor DTFT of the second pixel driving circuit 322 and a size of the narrowed portion of the driving thin film transistor DTFT of the third pixel driving circuit 323 are different. The first color, the second color and the third color are different colors.

Light emitting elements emitting light of different colors have different efficiencies. The light emitting element with a relatively high efficiency has a relatively small working current, and is more sensitive to voltage fluctuation and Mura. Therefore, it is needed to use the thin film transistor with relatively large subthreshold swing as the driving thin film transistor. Therefore, by making the size of the narrowed portion of the driving thin film transistor of the first pixel driving circuit, the size of the narrowed portion of the driving thin film transistor of the second pixel driving circuit and the size of the narrowed portion of the driving thin film transistor of the third pixel driving circuit different, the array substrate can make the driving abilities of the pixel driving circuits of sub-pixels emitting different colors match each other, so as to achieve a better display effect.

In some examples, the first color is red, the second color is green, and the third color is blue. Due to the high luminous efficiency of ordinary green light emitting elements, in this case, the size of the narrowed portion of the driving thin film transistor of the second pixel driving circuit is smaller than the size of the narrowed portion of the driving thin film transistor of the first pixel driving circuit and the size of the narrowed portion of the driving thin film transistor of the third pixel driving circuit. It should be noted that the size of the narrowed portion may be the average size of the narrowed portion in the first direction X, or the size of the extremely narrowed portion of the narrowed portion in the first direction X.

FIG. 22A is a schematic plan view of a driving thin film transistor provided by an embodiment of the present disclosure; FIG. 22B is a schematic plan view of another driving thin film transistor provided by an embodiment of the present disclosure.

As illustrated by FIG. 22A and FIG. 22B, the size of the narrowed portion of the driving thin film transistor shown in FIG. 22A is smaller than the size of the narrowed portion of the driving thin film transistor shown in FIG. 22B. It should be noted that the reference numerals of various components and regions in FIG. 22A and FIG. 22B can be found in FIG. 2.

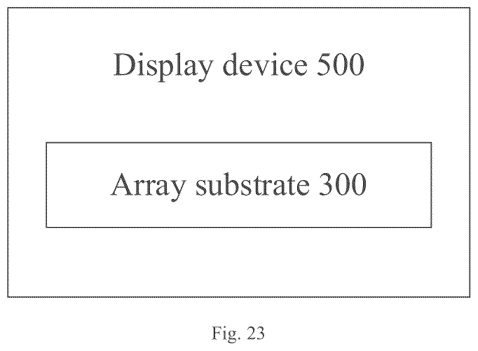

At least one embodiment of the present disclosure further provides a display device. FIG. 23 is a schematic plan view of a display device provided by an embodiment of the present disclosure. As illustrated by FIG. 23, the display device 500 includes the array substrate 300 described above. Therefore, the display device can have better display quality, ameliorate the Mura defect, and can also be applied to electronic products requiring high frequency, high resolution and large size.

In some examples, the display device may be an organic light emitting diode display device. Of course, the embodiments of the present disclosure include, but are not limited thereto, and the above display device can also be a light emitting diode display device or a quantum dot display device.

In some examples, the above display device can be an electronic product with a display function such as a mobile phone, a computer, a television, a navigator, a vehicle display, a tablet computer, an electronic picture frame, an electronic photo album, etc.

The following points need to be explained:
(1) In the drawings of the embodiments of the present disclosure, only the structure related to the embodiments of the present disclosure are involved, and other structures can refer to the general design.
(2) Features in the same embodiment and different embodiments of the present disclosure can be combined with each other without conflict.

The above is only the specific embodiments of the present disclosure, but the protection scope of the present disclosure is not limited thereto. Any person familiar with the technical field can easily think of changes or substitutions within the technical scope disclosed in the present disclosure, and the changes or substitutions should be included in the protection scope of the present disclosure. Therefore, the protection scope of the present disclosure should be based on the protection scope of the claims.

1. A thin film transistor, comprising:
an active layer, comprising a channel region and a first conductive region and a second conductive region separated by the channel region;
a first gate insulating layer, on a first side of the active layer; and
a first gate electrode, on a side of the first gate insulating layer away from the active layer,
wherein at least part of the first conductive region, at least part of the channel region and at least part of the second conductive region are arranged in a first direction, and the channel region comprises a narrowed portion, and an average size of the narrowed portion in the first direction is smaller than an average size of the channel region in the first direction.

2. The thin film transistor according to claim 1, wherein the first conductive region and the second conductive region are arranged opposite to each other and spaced part, and define a connection region between the first conductive region and the second conductive region, and the narrowed portion is in the connection region.

3. The thin film transistor according to claim 2, wherein the connection region comprises a center line extending in the first direction, and the narrowed portion is overlapped with the center line.

4. The thin film transistor according to claim 1, wherein the first conductive region is on a first side of the channel region and the second conductive region is on a second side of the channel region;
the narrowed portion is narrowed from the first side and the second side to a center line of the channel region extending in a second direction intersecting with the first direction.

5. The thin film transistor according to claim 1, wherein the channel region comprises a plurality of narrowed portions arranged in a second direction intersecting with the first direction.

6. The thin film transistor according to claim 5, wherein the plurality of narrowed portions are staggered in the first direction.

7. The thin film transistor according to claim 1, wherein at least one of the first conductive region and the second conductive region comprises a protrusion portion connected with the narrowed portion, and a shape of the protrusion portion is complementary to a shape of the narrowed portion.

8. The thin film transistor according to claim 1, wherein the channel region comprises a first edge and a second edge, the first edge is in contact with the first conductive region and the second edge is in contact with the second conductive region;
at least one of the first edge and the second edge comprises a bent portion, and the bent portion is bent from the first conductive region or the second conductive region to the channel region.

9. The thin film transistor according to claim 8, wherein the bent portion comprises at least one of an oblique line and an arc line, and an included angle between the oblique line and the first direction is less than 90 degrees.

10. The thin film transistor according to claim 8, wherein the first edge comprises a first bent portion bending from the first conductive region to the channel region, and the second edge comprises a second bent portion bending from the second conductive region to the channel region.

11. The thin film transistor according to claim 10, wherein the first bent portion and the second bent portion are overlapped in the first direction.

12. (canceled)

13. The thin film transistor according to claim 1, wherein a ratio of an area of the narrowed portion to an area of the channel region ranges from 1/16 to 3/16.

14. The thin film transistor according to claim 1, wherein a smallest size of the narrowed portion in the first direction is greater than or equal to 1 micron, and a ratio of a size of the narrowed portion in a second direction intersecting with the first direction to a size of the channel region in the second direction ranges from 10% to 20%.

15. The thin film transistor according to claim 1, further comprising:
a second gate insulating layer, on a second side of the active layer; and
a second gate electrode, on a side of the second gate insulating layer away from the active layer,
wherein an orthographic projection of the second gate electrode on the active layer completely covers an orthographic projection of the first gate electrode on the active layer.

16. The thin film transistor according to claim 15, wherein the channel region comprises a first edge and a second edge, the first edge is in contact with the first conductive region and the second side is in contact with the second conductive region;
a shortest distance between the first edge and an edge of an orthographic projection of the second gate electrode on the active layer is greater than 1.0 micron; a shortest distance between the second edge and an edge of the orthographic projection of the second gate electrode on the active layer is greater than 1.0 micron.

17. The thin film transistor according to claim 15, further comprising:
a first electrode, electrically connected with the first conductive region; and
a second electrode, electrically connected with the second conductive region,
wherein the first electrode is electrically connected with the second gate electrode.

18. (canceled)

19. An array substrate comprising:
a base substrate;
the thin film transistor according to claim 1, and
a plurality of pixel driving circuits, arranged in an array,
wherein each of the plurality of pixel driving circuits comprises a driving thin film transistor, and the driving thin film transistor comprises the thin film transistor.

20. (canceled)

21. The array substrate according to claim 19, wherein the plurality of pixel driving circuits comprise:
a first pixel driving circuit, configured to drive a first sub-pixel to emit light of a first color;
a second pixel driving circuit, configured to drive a second sub-pixel to emit light of a second color; and
a third pixel driving circuit, configured to drive a third sub-pixel to emit light of a third color,
wherein a size of the narrowed portion of the driving thin film transistor of the first pixel driving circuit, a size of the narrowed portion of the driving thin film transistor of the second pixel driving circuit and a size of the narrowed portion of the driving thin film transistor of the third pixel driving circuit are different.

22. A display device, comprising the array substrate claim 19.

23. A thin film transistor, comprising:
an active layer, comprising a channel region, and a first conductive region and a second conductive region separated by the channel region;
a first gate insulating layer, on a first side of the active layer; and
a first gate electrode, on a side of the first gate insulating layer away from the active layer,
wherein at least part of the first conductive region, at least part of the channel region and at least part of the second conductive region are arranged in a first direction;
the channel region comprises a first edge and a second edge, the first edge is in contact with the first conductive region and the second edge is in contact with the second conductive region, and at least one of the first edge and the second edge comprises a bent portion, and the bent portion is bent from the first conductive region or the second conductive region to the channel region.

24. (canceled)

25. (canceled)
